(19) United States
(12) Patent Application Publication
(10) Pub. No.: US 2019/0379007 A1
(43) Pub. Date: Dec. 12, 2019

(54) MANUFACTURING METHOD FOR HIGH-RESOLUTION ARRAY ORGANIC FILM, AND USE THEREOF

(71) Applicant: South China University of Technology, Guangzhou City (CN)

(72) Inventors: Yuguang Ma, Guangzhou (CN); Linlin Liu, Guangzhou (CN); Rong Wang, Guangzhou (CN)

(73) Assignee: South China University of Technology, Guangzhou City (CN)

(21) Appl. No.: 16/341,667

(22) PCT Filed: Nov. 14, 2017
(86) PCT No.: PCT/CN2017/110891

§ 371 Date: Apr. 12, 2019

(30) Foreign Application Priority Data
May 24, 2017 (CN) 201710373549.9

(51) Int. Cl. H01L 51/56; H01L 51/00

(52) U.S. Cl. CPC H01L 51/56; H01L 51/0014; H01L 51/0007

(57) ABSTRACT

The present disclosure discloses a manufacturing method for a high-resolution array organic film, and use thereof The high-resolution array organic film manufacturing method performs, by means of electrochemical deposition, polymerization of electrically active monomers on a high-resolution display screen array substrate to deposit and form a high-resolution array organic film. Also disclosed is a use of the manufactured high-resolution array organic film in manufacturing of OLED display screens. By employing electrochemical deposition to deposit the high-resolution array film on the high-resolution array substrate, the present disclosure provides a high-resolution film forming technique having simple operation, a low cost, film controllability, and precision up to 10 μM.

### CROSS-REFERENCE TO RELATED APPLICATIONS

This application claims priority to China Patent Application No. CN 201710373549.9 filed May 24, 2017, and International Patent Application No. PCT/CN2017/110891 filed Nov. 14, 2017, both of which are hereby incorporated by reference in their entirety.

### FIELD OF THE DISCLOSURE

The present disclosure relates to a manufacturing method for a high-resolution array organic film, and use thereof.

### BACKGROUND OF THE DISCLOSURE

Resolution is one of the most important performance indicators of a display. When the resolution of the display becomes higher, the picture becomes finer and more information can be displayed in the same screen area. High resolution means that the pixel density in the image is high and the pixel size is small, which makes the cost and difficulty of manufacturing increase.

At present, the patterned thin film preparation technology of organic electroluminescent display (OLED) mainly includes fine metal mask evaporation technology, inkjet printing technology, and laser thermal transfer imaging technology.

The fine metal mask evaporation technology is currently the most commonly used thin film preparation technology. This technology, by utilizing a fine metal mask and a CCD pixel alignment technique, is to heat and evaporate the material under high vacuum conditions and then get the material cooled on the substrate to form a patterned film. This technology is simple and mature, and has been widely used in the preparation of organic light emitting diode (OLED) display screens. However, the equipment for the fine metal mask evaporation is complicated and costly; besides, limited by the metal etching technology, the patterning precision of mask evaporation technology can only reach the level of several tens of microns to several microns; in addition, high-resolution metal masks are so thin that they are difficult to accurately align in a large display screen. Therefore, in the process of industrialization of OLEDs towards high resolution and large size, the metal mask technology faces more demanding requirements of graphic dimensional accuracy and positioning accuracy.

The inkjet printing technology is an energy-saving and environment-friendly patterned film preparation technology. This technology achieves patterning by using a print nozzle to spray a small amount of solution (several picoliters) into a pixel pit. It can fully utilize the solution processing characteristics of polymers and certain small molecules, and is essentially non-selective to the substrate, simple to operate, and material saving. However, printing accuracy is a big problem in inkjet printing. For the inkjet printing technology, the smaller the ink droplet, the harder it is to drop precisely onto the pixel surface. Experiments have shown that when the ink droplet has a diameter less than 10 μm, it is difficult to overcome the air resistance to drop onto the substrate. In addition, inkjet printing has high requirements on ink; since the evaporation speed of ink at different positions is inconsistent, a “coffee ring effect” is likely to occur during film formation, resulting in difficulty in controlling the film formation.

The laser thermal transfer imaging technology uses a photothermal conversion material to convert the light energy of a laser into thermal energy to get the coating patterned. The technology has high etching precision, but a low utilization ratio of materials, serious waste, and a high production cost, which limits its large-scale industrialization process.

High resolution means that the display screen substrate has a high pixel density and a small pixel size. For the electrochemical deposition process, when the pixel electrode is less than 25 μm at least in one dimension, it becomes a strip-shaped microelectrode. Since the size of the microelectrode is close to the thickness of the diffusion layer, there are both axial diffusion in the vertical direction and radial diffusion on the surface of the electrode, when the thickness of the diffusion layer is larger than the size of the electrode. Therefore, the mass transfer rate on the surface of the microelectrode is not uniform, and neither is the film deposited on the microelectrode. However, the film used in the OLED display is required to be uniform, otherwise the device is prone to leakage current, uneven luminescence or even short circuit, etc. Therefore, nonuniform films deposited on a single microelectrode are difficult to apply to the field of OLED display. However, for array microelectrodes, the situation is quite special. Since the thickness of the diffusion layer changes with time and the interval between the array electrodes is relatively small, when the time is long (about several tens of milliseconds), the diffusion layer increases, and the separate diffusion layers will fuse together to become linearly diffused as a plate electrode. All the pixels in the display screen array substrate are array microelectrodes, making the entire display screen array substrate equivalent to one plate electrode, thus weakening the microelectrode effect. Therefore, the more and denser the pixels on the display screen array substrate, the more advantageous it is for obtaining a uniform film. In principle, the pixel electrode array on the high-resolution display screen array substrate is used as the working electrode in the electrolytic cell system, and the electrically active monomer is polymerized on the array pixel electrode of the display screen array substrate to deposit and form a thin film, thereby obtaining a high-resolution array film. Therefore, the electrochemical deposition technology can be used as a deposition method for high-resolution array films.

An improved electrochemical deposition technology is presented which provides a method of forming a polymer film on an electrode by utilizing an electrically active monomer to undergo oxidation or reduction coupling reaction at the interface between the electrode and the solution. This technology, characterized by a simple process and low cost, can precisely control the properties of the film, such as morphology, thickness and aggregate structure, by selecting the electrochemical deposition method and conditions. The electrochemical deposition technology can complete the synthesis and directional deposition of polymer films in one step. By employing electrochemical deposition to deposit the high-resolution array film on the high-resolution display screen array substrate, the present disclosure provides an improved high-resolution film forming technique having simple operation, a low cost, film controllability, and precision up to 10 μm.

### OVERVIEW OF THE DISCLOSURE

It is an object of the present disclosure to provide a manufacturing method for a high-resolution array organic film, and use thereof. The high resolution described in the present disclosure means that the resolution is 200 ppi and above.

The present disclosure adopts the following technical solution:

The high-resolution array organic film manufacturing method performs, by means of electrochemical deposition, polymerization of electrically active monomers on an array substrate of a high-resolution display screen to deposit and form a high-resolution array organic film.

The high-resolution array organic film manufacturing method comprise the following steps:

1) Preparing a high-resolution display screen array substrate, the display screen array substrate comprising a base substrate and a pixel electrode layer, pixel electrodes in the pixel electrode layer being distributed in a rectangular array;

2) establishing an electrolytic cell system, with the pixel electrode of the high-resolution display screen array substrate as a working electrode and an electrically active monomer solution as an electrolytic solution;

3) applying an electrochemical deposition signal to the electrolytic cell, such that the electrically active monomer is polymerized on the surface of the pixel electrode to deposit and form a film; and

4) washing and drying the film obtained in the step 3) to obtain the high-resolution array organic film.

The electrically active monomer has a chemical structural formula of XYn, wherein X is a luminescent group and at least one of benzene, biphenyl, styrene, naphthalene, anthracene, phenanthrene, anthracene, anthracene, and derivatives thereof, Y is an electrically active group and at least one of furan, pyrrole, thiophene, carbazole, ethylene, acetylene, aniline, diphenylamine, and triphenylamine, and n is the number of Y, with X and Y linked to each other by at least one of an alkyl chain, an alkoxy chain, and an oxy chain.

Further, the electrically active monomer has the following chemical structural formula:

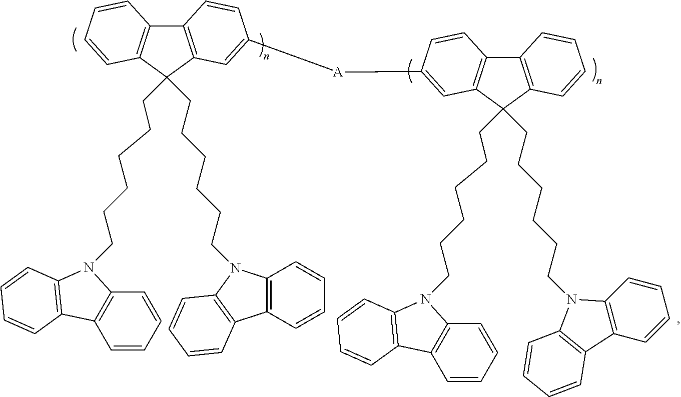

where A is one of

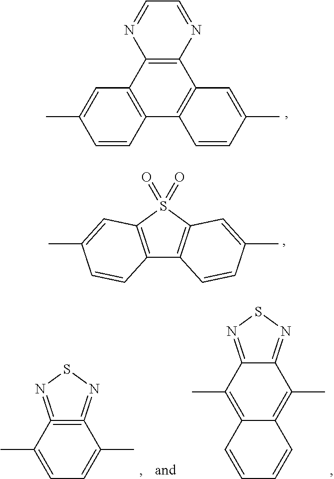

and n is 1 or 2.

The electrolytic cell system described in the step 2) is a three-electrode system, wherein the reference electrode is one of an Ag/Ag⁺ electrode, an Ag/AgCl electrode, a hydrogen standard electrode, and a saturated calomel electrode, and the auxiliary electrode is a Ti electrode or a Pt electrode.

A supporting electrolyte of the electrolytic solution described in the step 2) is a combination of anions and cations, the anions being at least one of perchlorate ions, tetrafluoroborate ions, hexafluorophosphate ions, and hexafluoroarsenate ions, the cations being at least one of sodium ions, potassium ions, lithium ions, ammonium ions, tetramethylammonium ions, tetraethylammonium ions, and tetra-n-butylammonium ions.

The solvent of the electrolytic solution described in the step 2) is at least one of acetonitrile, dichloromethane, polycarbonate, N,N-dimethylformamide, tetrahydrofuran, ethanol, chlorobenzene, and trifluoroborate ether.

The electrochemical deposition signal described in the step 3) has an input voltage of −3 to 3 V and a scanning speed of 1-5000 mV/s.

Also provided is a use of the above manufactured high-resolution array organic film in manufacturing of OLED display screens.

The present disclosure has at least the following beneficial effects:

By employing electrochemical deposition to deposit the high-resolution array film on the high-resolution array substrate, the present disclosure provides a high-resolution film forming technique having simple operation, a low cost, film controllability, and precision up to 10 μm.

Some of the beneficial effects are as follows:

1. The present disclosure adopts simple equipment and has a low cost, can be carried out under normal temperature and normal pressure, saves raw materials, and can complete synthesis and precise deposition of polymer films in one time.

2. The electrodeposited film of the present disclosure has a precisely controlled deposition position and is thus easily patterned, and properties of the film including morphology and thickness can be conveniently controlled by deposition conditions.

3. The present disclosure, taking advantage of the fact that the electrochemical behavior of the array microelectrode is similar to that of a plate electrode, avoids the deposition of a nonuniform film caused by the microelectrode effect, and produces a uniform and flat high-resolution array film, providing a simple and effective method for the preparation of a high-resolution array film.

### BRIEF DESCRIPTION OF THE DRAWINGS

FIG. 1 is a schematic view showing the diffusion on different electrode surfaces.

FIG. 2 is a schematic view showing the connection of an electrolytic cell circuit according to an example of the present disclosure;

FIG. 3 is a layout of a display screen array substrate according to an example of the present disclosure;

FIG. 4 shows a multi-cycle cyclic voltammetry curve of an electrically active monomer on a display screen array substrate according to an example of the present disclosure; and

FIG. 5 shows a micrograph of a film deposited by an electrically active monomer on a display screen array substrate according to an example of the present disclosure.

### DETAILED DESCRIPTION OF THE EMBODIMENTS

The high-resolution array organic film manufacturing method performs, by means of electrochemical deposition, polymerization of electrically active monomers on a high-resolution display screen array substrate to deposit and form a high-resolution array organic film.

The high-resolution array organic film manufacturing method comprise the following steps:

1) Preparing a high-resolution display screen array substrate, the display screen array substrate comprising a base substrate and a pixel electrode layer, pixel electrodes in the pixel electrode layer being distributed in a rectangular array:

2) establishing an electrolytic cell system, with the pixel electrode of the high-resolution display screen array substrate as a working electrode and an electrically active monomer solution as an electrolytic solution:

3) applying an electrochemical deposition signal to the electrolytic cell, such that the electrically active monomer is polymerized on the surface of the pixel electrode to deposit and form a film; and

4) washing and drying the film obtained in the step 3) to obtain the high-resolution array organic film.

The electrically active monomer has a chemical structural formula of XYn, wherein X is a luminescent group and at least one of benzene, biphenyl, styrene, naphthalene, anthracene, phenanthrene, anthracene, anthracene, and derivatives thereof, Y is an electrically active group and at least one of furan, pyrrole, thiophene, carbazole, ethylene, acetylene, aniline, diphenylamine, and triphenylamine, and n is the number of Y, with X and Y linked to each other by at least one of an alkyl chain, an alkoxy chain, and an oxy chain.

The electrically active monomer may have the following chemical structural formula:

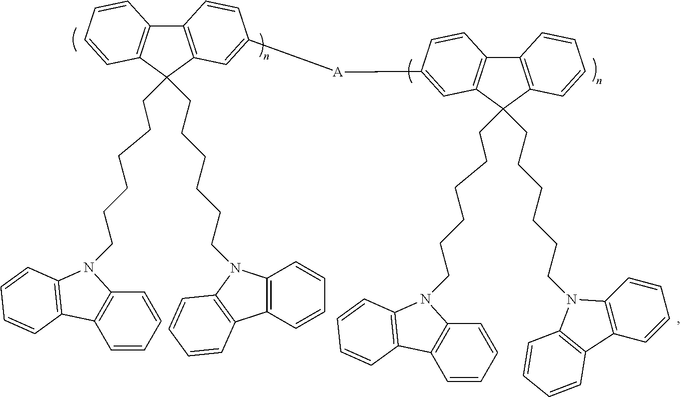

where A is one of

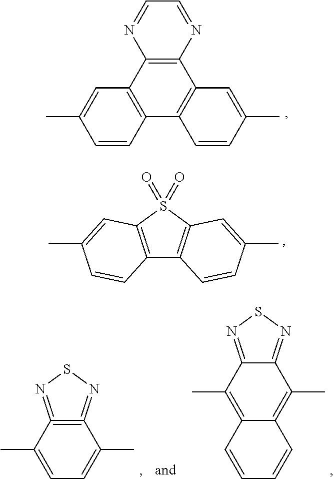

and n is 1 or 2. For the synthesis method of such electrically active monomers, please refer to Reference 1 (Yao L, Xue S, Wang Q, Et Al. RGB Small Molecules Based on a Bipolar Molecular Design for Highly Efficient Solution-Processed Single-Layer OLEDs. Chem. Eur. J. 2012, 18, 2707-2714).

Further, the electrically active monomer may have the following chemical structural formula:

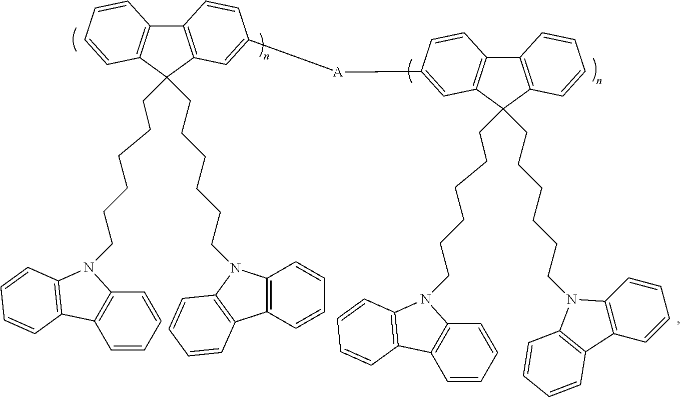

where A is one of

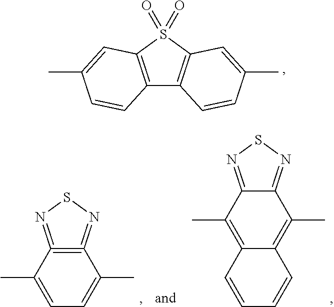

and n is 1 or 2.

Still further, the electrically active monomer may have the following chemical structural formula:

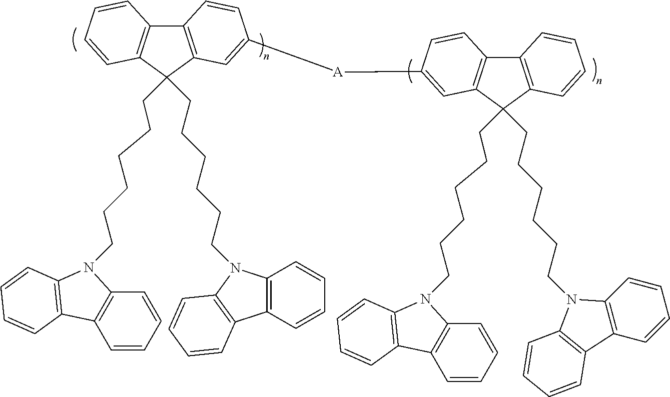

where A is

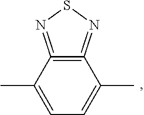

and n is 2. That is, the chemical structural formula of the electrodeposition monomer is as follows:

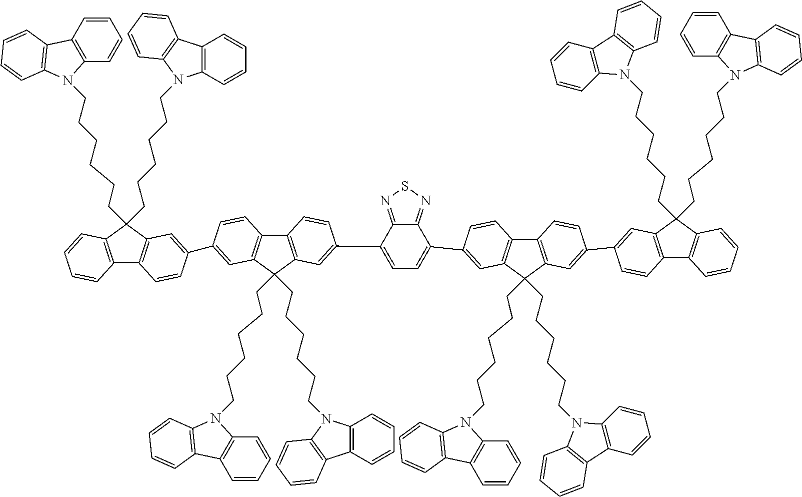 [SMILES: c1ccc2c(c1)-c1ccc(-c3ccc4c(c3)C(CCCCCCn3c5ccccc5c5ccccc53)(CCCCCCn3c5ccccc5c5ccccc53)c3cc(-c5ccc(-c6ccc7c(c6)C(CCCCCCn6c8ccccc8c8ccccc86)(CCCCCCn6c8ccccc8c8ccccc86)c6cc(-c8ccc9c(c8)C(CCCCCCn8c%10ccccc%10c%10ccccc%108)(CCCCCCn8c%10ccccc%10c%10ccccc%108)c8ccccc8-9)ccc6-7)c6nsnc56)ccc3-4)cc1C2(CCCCCCn1c2ccccc2c2ccccc21)CCCCCCn1c2ccccc2c2ccccc21]

The present disclosure names the electrically active monomer OCBzC.

The electrolytic cell system described in the step 2) is a three-electrode system, wherein the reference electrode is one of an Ag/Ag⁺ electrode, an Ag/AgCl electrode, a hydrogen standard electrode, and a saturated calomel electrode, and the auxiliary electrode is a Ti electrode or a Pt electrode. Further, the electrolytic cell system described in the step 2) is a three-electrode system, where the reference electrode is an Ag/Ag⁻ electrode and the auxiliary electrode is a Ti electrode.

The concentration of the electrically active monomer solution in the step 2) is 10⁻⁶-10³ M; further, the concentration of the electrically active monomer solution in the step 2) is 1.6×10⁻⁴ M.

A supporting electrolyte of the electrolytic solution described in the step 2) is a combination of anions and cations, the anions being at least one of perchlorate ions, tetrafluoroborate ions, hexafluorophosphate ions, and hexafluoroarsenate ions, the cations being at least one of sodium ions, potassium ions, lithium ions, ammonium ions, tetramethylammonium ions, tetraethylammonium ions, and tetra-n-butylammonium ions; further, the supporting electrolyte of the electrolytic solution described in the step 2) is tetrabutylammonium hexafluorophosphate; still further, the supporting electrolyte is a 0.1 M solution of tetrabutylammonium hexafluorophosphate.

The solvent of the electrolytic solution described in the step 2) is at least one of acetonitrile, dichloromethane, polycarbonate, N,N-dimethylformamide, tetrahydrofuran, ethanol, chlorobenzene, and trifluoroborate ether; further preferably, the solvent of the electrolytic solution described in the step 2) is at least one of acetonitrile, dichloromethane, polycarbonate, N,N-dimethylformamide, and tetrahydrofuran; still further, the solvent of the electrolyte described in the step 2) is a mixture of acetonitrile and dichloromethane, wherein the volume ratio of acetonitrile to dichloromethane is 2:3.

The electrochemical deposition signal described in the step 3) has an input voltage of −3 to 3 V and a scanning speed of 1-5000 mV/s; further preferably, the electrochemical deposition signal described in the step 3) has an input voltage of −1 to 1 V and a scanning speed of 10-100 mV/s; still further, the electrochemical deposition signal described in the step 3) has an input voltage of −0.5 to 0.87 V and a scanning speed of 50 mV/s.

Also provided is a use of the above manufactured high-resolution array organic film in manufacturing of OLED display screens.

Further, in the above application, the high-resolution array organic film is used as the light-emitting layer, and the OLED display screen is prepared by vacuum evaporation.

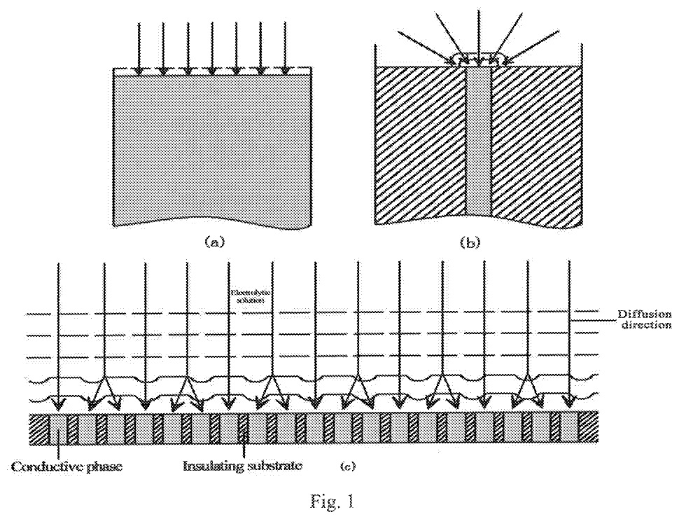

A schematic diagram of the diffusion on different electrode surfaces is shown in FIG. 1, where (a) is a schematic diagram of diffusion on a plate electrode, (b) is a schematic diagram of diffusion on a single strip-shaped microelectrode, and (c) is a schematic diagram of diffusion on an array microelectrode.

The inventive concept of the present disclosure will be further described below with reference to FIG. 1. With the size of the conventional electrode much larger than the thickness of the diffusion layer, the diffusion on the surface of the conventional electrode is a semi-infinite diffusion perpendicular to the surface of the electrode (as shown in (a) of FIG. 1). Therefore, the diffusion on the electrode surface is uniform (that is, the mass transfer rate is uniform), and thus the film deposited on the surface of the conventional electrode tends to be uniform. High resolution means that the display screen substrate has a high pixel density and a small pixel size. For the electrochemical deposition process, when the pixel electrode is less than 25 μm at least in one dimension, it becomes a strip-shaped microelectrode, and the size of which is close to the thickness of the diffusion layer. When the thickness of the diffusion layer is larger than the size of the electrode, there are both axial diffusion in the vertical direction and radial diffusion on the surface of the electrode. Therefore, the mass transfer rate on the surface of the microelectrode is not uniform (as shown in (b) of FIG. 1), and neither is the film deposited on the microelectrode. However, the film used in the OLED display is required to be uniform, otherwise the device is prone to leakage current, uneven luminescence or even short circuit, etc. . . . . Therefore, nonuniform films deposited on a single microelectrode are difficult to apply to the field of OLED display. However, for array microelectrodes, the situation is quite special. Since the thickness of the diffusion layer changes with time and the interval between the array electrodes is relatively small, when the time is long (about several tens of milliseconds), as the diffusion layer increases, the separate diffusion layers will fuse together and become linearly diffused (as shown in (c) of FIG. 1), making these electrodes behave like a plate electrode. All the pixels in the display screen array substrate are array microelectrodes, with the entire display screen array substrate equivalent to one plate electrode, thus weakening the microelectrode effect. Therefore, the more and denser the pixels on the display screen array substrate, the more advantageous it is for obtaining a uniform film. In principle, the array pixel electrode on the high-resolution display screen array substrate is used as the working electrode in the electrolytic cell system, and the electrically active monomer is polymerized on the array pixel electrode of the display screen array substrate to deposit and form a thin film, thereby obtaining a high-resolution array film. Therefore, the electrochemical deposition technology can be used as a deposition method for high-resolution array films.

The contents of the present disclosure will be further described in detail below by way of specific examples.

### EXAMPLES

1. Preparation of high-resolution array organic film.

(1) Using all the pixel electrodes on the display screen array substrate as the working electrode:

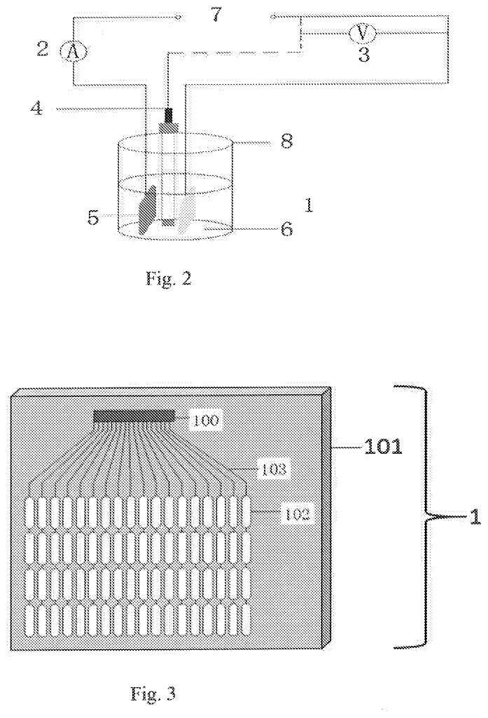

With reference to FIG. 2, the present disclosure provided an electrochemical workstation 7, an ammeter 2, a voltmeter 3, a high-resolution display screen array substrate 1, a reference electrode 4, an auxiliary electrode 5, an electrolytic solution 6, and an electrolytic cell 8. The high-resolution display screen array substrate 1 and the auxiliary electrode 5 were respectively connected to the electrochemical workstation 7, and immersed in the electrolytic cell 8 containing the electrolytic solution 6, the electrolytic solution 6 containing the electrically active monomer with an electrically active group. The reference electrode 4 was disposed between the auxiliary electrode 5 and the display screen array substrate 1, and connected to the electrochemical workstation 7. The schematic diagram of the electrolytic cell circuit connection is shown in FIG. 2.

The layout of the high-resolution display screen array substrate 1 is as shown in FIG. 3. The display screen array substrate 1 comprised a base substrate 101,and a pixel electrode layer 102 disposed on the base substrate 101.The pixel electrode layer 102 comprised a plurality of pixel electrodes distributed in a matrix, and all of the pixel electrodes were connected to the common electrode 100 through the metal wire 103, with an electrodeposition signal inputted to all the pixel electrode surfaces through the common electrode. The display screen array substrate, comprising pixel electrodes distributed in a 288×64 array, had a pixel size of 40 μm×120 μm, an effective size of 10 μm×100 μm, a resolution of 210 ppi, and an aperture opening ratio of 20%.

(2) Outputting an electrodeposition signal through the electrochemical workstation, and depositing an array film on all the pixel electrodes of the corresponding display screen array substrate of the electrolytic cell circuit in the energized state:

The electrically active monomer used in this example is the above-mentioned OCBzC, which is a yellow-green monomer. The synthesis procedure was described in Reference 1. The molecular structure of the monomer mainly consists of two parts: 1) A luminescent center: the luminescent center is mainly composed of fluorene as the basic building unit, as well as an appropriate proportion of the electron acceptor, namely diazosulfide; and 2) an electrically active center: the electrically active center is a carbazole group attached to the luminescent center by a flexible alkyl chain of appropriate length.

The electrically active yellow-green monomer OCBzC was dissolved in a mixed solution of acetonitrile and dichloromethane in a volume ratio of 2:3 at a concentration of 1.6×10⁻⁴ M. The supporting electrolyte was tetrabutylammonium hexafluorophosphate at a concentration of 0.1M. The luminescent compound used in the present disclosure was slightly soluble in acetonitrile. To increase the concentration of the compound, dichloromethane was added to increase the solubility of the luminescent compound.

The process of depositing a yellow-green OCBzC film on a display screen array substrate is as follows:

Depositing the OCBzC luminescent film on the display screen array substrate: All the pixel electrodes of the high-resolution display screen array substrate were used as the working electrode, which was placed in the electrolytic solution of the electrically active yellow-green monomer OCBzC. The electrochemical workstation inputted the electrodeposition signals to the common electrode on the display screen array substrate.

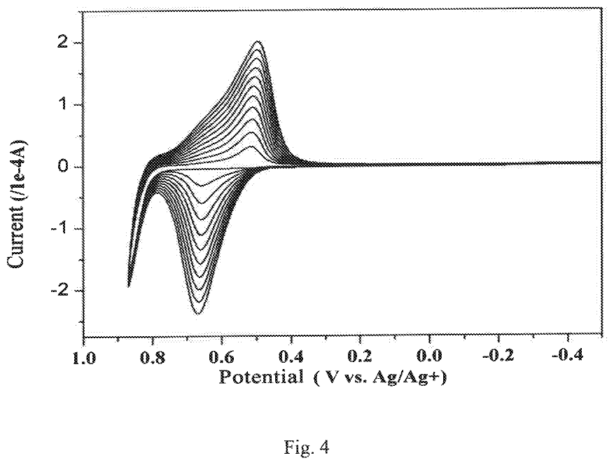

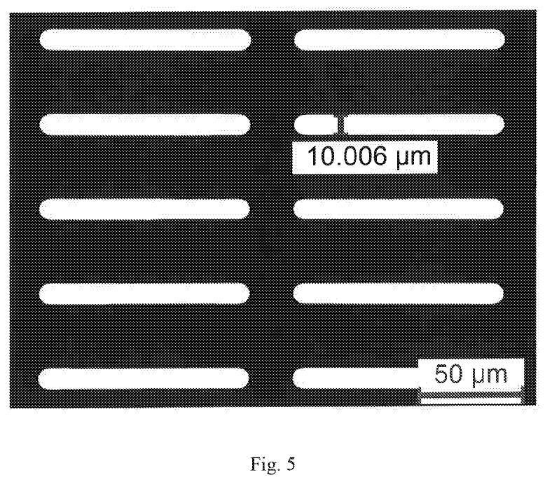

The electrolytic solution was a mixed solution of 1.6×10⁻⁴ M OCBzC in acetonitrile/dichloromethane (in a volume ratio of 2:3), the supporting electrolyte was 0.1 M tetrabutylammonium hexafluorophosphate, and the reference electrode was 0.01 M Ag/Ag⁺ electrode, and the auxiliary electrode was a metal titanium plate. The electrochemical workstation inputted an electrodeposition signal of −0.5 to 0.87 V to the common electrode on the display screen array substrate with respect to the reference electrode. The scanning speed was 50 mV/s, and the number of scans was 11 circles. The obtained cyclic voltammetry curve is shown in FIG. 4. As can be seen from FIG. 4, as the number of scans increased, the oxidizing and reducing peak currents sequentially increased, indicating the continuous growth of the electrodeposited film. A micrograph of the OCBzC film deposited on the display screen array substrate is shown in FIG. 5, with 50 μm in the lower right corner of FIG. 5 as a scale. The electrode reaction of the OCBzC monomer on the high-resolution display screen array substrate had good reversibility, and the deposited film was uniform, flat and complete with an accuracy of thickness up to 10 μm. The results measured by atomic force microscopy showed that the roughness of the film was 1.98 nm.

2. Application of high-resolution array organic film.

The OCBzC film deposited in the above example was used as a light-emitting layer of an OLED display screen to prepare a high-resolution OLED display screen.

The process for preparing an organic light emitting diode device using the high-resolution array film of this example is as follows:

The cleaned electrodeposited high-resolution array film was dried in vacuum at room temperature, and then vapor-deposited under a vacuum less than 3×10⁻⁴ Pa with 1,3,5-tris(1-phenyl-1H-benzimidazol-2-yl)benzene (TPBi) as an electron transport layer as well as cesium fluoride (CsF) and aluminum metal (Al) as the cathode of the OLED device, with the thickness of the vapor-deposited TPBi, CsF and Al being 30 nm, 1 nm and 120 nm, respectively. The device structure was ITO/Au/OCBzC/TPBi/CsF/Al. The electrodeposited OCBzC luminescent film had a thickness of about 80 nm, and Au had a thickness of 1 nm. Once the device was fabricated, the device was packaged to obtain a high-resolution OLED display screen.

With a voltage applied to the anode (ITO) and cathode (Al) of the packaged OLED display screen by a constant voltage power supply, a high-resolution OLED display screen emitting yellow-green light can be obtained.

3. Comparative analysis.

(1) Compared with the inkjet printing technology, the electrochemical deposition method of the present disclosure has no alignment problem and thus no alignment error, and the film is accurately positioned and deposited, completely covering the pixel surface in uniform and flat distribution. It is easy to electrodeposit a high-resolution uniform flat film on a high-resolution substrate; the higher the pixel density of the display screen (i.e., the higher the aperture opening ratio), the more advantageous it is for obtaining a uniform flat film.

However, in the process of using the inkjet printing technology, droplet offset may occur during printing, causing droplets to deviate from the pixel pit and resulting in positioning errors, which seriously affects the printing accuracy, as described in Reference 2 (Lee, Dongwon, et al. “P-66: Ink Jet Printed Full Color Polymer LED Displays.” SID Symposium Digest of Technical Papers. 2005, 36, 527-529). Moreover, since the evaporation speed of ink at different positions is inconsistent, the formed film tends to be nonuniformly distributed; the higher the pixel density and the smaller the pixel size, the more difficult it is to accurately position and the more likely it is to cause cross interference. Reference 2 shows a nonuniform film formed when a PEDT:PSS polymer solution was printed on a pixel having a size of 103 μm×309 μm.

(2) Compared with the fine metal mask evaporation technology, the present disclosure has at least the following advantages:

A. The fine metal mask evaporation technology is complex, requires high vacuum and a fine metal mask, and has a high cost. The present disclosure requires simple equipment and easy operation, and can complete the experimental process under normal temperature and normal pressure without a fine mask and high vacuum, thus having a low cost.

B. The fine metal mask evaporation technology needs to align the fine mask with the CCD pixels; the denser the pixels, the lower the accuracy of the alignment and the greater the alignment error. The present disclosure has no alignment problem and thus no alignment error, with the film accurately positioned and deposited; the denser the pixels on the display screen, the more advantageous it is for obtaining a uniform flat film.

In general, the electrochemical deposition technology is a method of forming a polymer film on an electrode by utilizing an electrically active monomer to undergo oxidation or reduction coupling reaction at the interface between the electrode and the solution. This technology, characterized by a simple process and low cost, can precisely control the properties of the film, such as morphology, thickness and aggregate structure, by selecting the electrochemical deposition method and conditions. The electrochemical deposition technology can complete the synthesis and directional deposition of polymer films in one step. Therefore, the electrochemical deposition technology of the present disclosure has the following characteristics:

1. The pixels distributed in an array on the display screen array substrate are similar to array microelectrodes, and the electrochemical behavior on these array microelectrodes is similar to that on a plate electrode, which greatly weakens the microelectrode effect, such that a uniform flat film similar to a film on the plate electrode can be obtained by electrochemical deposition on the display screen array substrate.

2. The more pixels on the display screen array substrate and the higher the density, the more advantageous it is for weakening the microelectrode effect; therefore, the large-size and high-density display screen array substrate is more advantageous for obtaining a uniform flat electrochemical deposition film.

3. By using the electrochemical deposition technology, it is easy to deposit a uniform flat high-resolution array film on the high-resolution display screen array substrate, the experimental equipment is simple and easy to operate, the experimental process can be completed under normal temperature and normal pressure, and there is no need for a fine mask and high vacuum.

The above-described examples are preferred embodiments of the present disclosure, but the embodiments of the present disclosure are not limited thereto, and any other alterations, modifications, substitutions, combinations and simplifications that are made without departing from the spirit and scope of the present disclosure are intended to be equivalents and are included in the scope of protection of the present disclosure.

What is claimed is:

1. A manufacturing method for a high-resolution array organic film, comprising: a method of electrochemical deposition, polymerization of electrically active monomers on an array substrate of a high-resolution display screen to deposit and form a high-resolution array organic film.

2. The manufacturing method for a high-resolution array organic film according to claim 1, wherein the method comprises the following steps:
1) preparing the high-resolution display screen array substrate, the display screen array substrate comprising a base substrate and a pixel electrode layer, pixel electrodes in the pixel electrode layer being distributed in a rectangular array;
2) establishing an electrolytic cell system, with the pixel electrode of the high-resolution display screen array substrate as a working electrode and an electrically active monomer solution as an electrolytic solution;
3) applying an electrochemical deposition signal to the electrolytic cell, such that the electrically active monomer is polymerized on the surface of the pixel electrode to deposit and form a film; and
4) washing and drying the film obtained in the step 3) to obtain the high-resolution array organic film.

3. The manufacturing method for a high-resolution array organic film according to claim 1, wherein the electrically active monomer has a chemical structural formula of XYn, wherein X is a luminescent group and at least one of benzene, biphenyl, styrene, naphthalene, anthracene, phenanthrene, anthracene, anthracene, and derivatives thereof, Y is an electrically active group and at least one of furan, pyrrole, thiophcnc, carbazole, ethylene, acetylene, aniline, diphenylaminc, and triphenyl amine, and n is the number of Y, with X and Y linked to each other by at least one of an alkyl chain, an alkoxy chain, and an oxy chain.

4. The manufacturing method for a high-resolution array organic film according to claim 3, wherein the electrically active monomer has the following chemical structural formula: 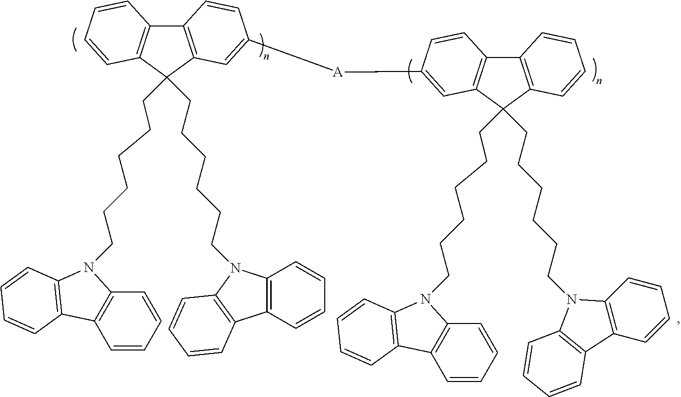
where A is one of 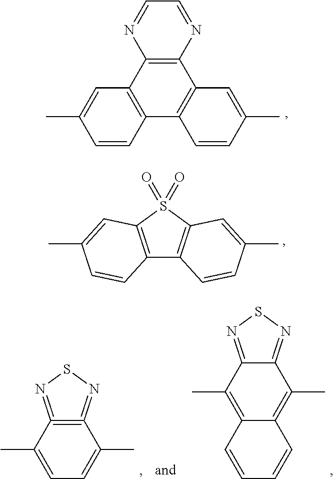
and n 1 or 2.

5. The manufacturing method for a high-resolution array organic film according to claim 2, wherein the electrolytic cell system described in the step 2) is a three-clcctrode system, wherein the reference electrode is one of an Ag/Ag⁺ electrode, an Ag/AgCl electrode, a hydrogen standard electrode, and a saturated calomel electrode, and the auxiliary electrode is a Ti electrode or a Pt electrode.

6. The manufacturing method for a high-rcsolution array organic film according to claim 5, wherein a supporting electrolyte of the electrolytic solution described in the step 2) is a combination of anions and cations, the anions being at least one of perchlorate ions, tetrafluoroboratc ions, hexafluorophosphale ions, and hexafluoroarsenate ions, the cations being at least one of sodium ions, potassium ions, lithium ions, ammonium ions, tetramethylammonium ions, tetraethylammonium ions, and tetra-n-butylammonium ions.

7. The manufacturing method for a high-resolution array organic film according to claim 5, wherein the solvent of the electrolytic solution described in the step 2) is at least one of acetonitrile, dichloromethanc, polycarbonate, N,N-dimethylformamide, tetrahydrofuran, ethanol, chlorobenzenc, and trifluoroborate ether.

8. The manufacturing method for a high-resolution array organic film according to claim 2, wherein the electrochemical deposition signal described in the step 3) has an input voltage of about −3 to 3 V and a scanning speed of about 1-5000 mV/s.

9. The manufacturing method for a high-rcsolution array organic film according to claim 1, wherein the manufacturing method results in making OLHD display screens.
